(19) United States
(12) Patent Application Publication
(10) Pub. No.: US 2024/0128052 A1
(43) Pub. Date: Apr. 18, 2024

(54) INDUCTIVELY COUPLED PLASMA APPARATUS WITH NOVEL FARADAY SHIELD

(71) Applicant: Applied Materials, Inc., Santa Clara, CA (US)

(72) Inventors: Costel Biloiu, Rockport, MA (US); Adam Calkins, Newmarket, NH (US); Benjamin Alexandrovich, Brookline, MA (US); Solomon Belangedi Basame, Middleton, MA (US); Kevin M. Daniels, Lynnfield, MA (US)

(73) Assignee: Applied Materials, Inc., Santa Clara, CA (US)

(21) Appl. No.: 17/964,621

(22) Filed: Oct. 12, 2022

(51) Int. Cl. H01J 37/32; H05H 1/46

(52) U.S. Cl. CPC H01J 37/3211; H05H 1/4652

(57) ABSTRACT

An antenna assembly, comprising: an antenna; a dielectric enclosure surrounding the antenna; and a Faraday shield, disposed around the antenna, and arranged between the antenna and the dielectric enclosure, wherein the Faraday shield comprises a non-uniform opacity along an antenna axis of the antenna, wherein a first opacity of the Faraday shield at a first position along the antenna axis is greater than a second opacity of the Faraday shield at a second position along the antenna axis of the antenna.

### FIELD OF THE DISCLOSURE

The disclosure relates generally to processing apparatus, and more particularly to plasma based ion sources.

### BACKGROUND OF THE DISCLOSURE

In the present day, plasmas are used to process substrates, such as electronic devices, for applications such as substrate etching, layer deposition, ion implantation, and other processes. Some processing apparatus employ a plasma chamber that generates a plasma to act as an ion source for substrate processing. An ion beam may be extracted through an extraction assembly and directed to a substrate in an adjacent chamber. This plasma may be generated in various ways.

In various commercial systems, an antenna is disposed outside the plasma chamber, proximate to a dielectric window. The antenna is then excited using an RF power supply. The electromagnetic energy generated by the antenna then passes through the dielectric window to excite feed gas disposed within the plasma chamber by inductive coupling. This configuration provides a relatively simple construction, and may generate dense plasmas suitable for generating a high current ion beam using extraction through an extraction aperture that may be placed centrally within the plasma chamber. However, such inductively coupled plasmas (ICP) may tend to have a peaked plasma density in the middle of the chamber, and may not be ideal for long apertures or for multi-aperture high current ion beam systems, where two or more apertures are arranged as parallel slots along one edge of the plasma chamber.

Another approach may to provide an ICP antenna within a plasma source to excite the gas in the surrounding chamber. In such case, the antenna will be protected by a material that acts as an rf window, where the rf window material may be shaped into an enclosure that surrounds the antenna. However, such windows may be susceptible to degradation during plasma source operation. An ideal ICP system should have just inductive coupling to power the plasma. However, an RF antenna also couples capacitively with the plasma in practical implementations. A small capacitive coupling from antenna to plasma is desired because plasma is ignited capacitively. However, too much capacitive coupling is detrimental to the plasma source because a relatively higher degree of capacitive coupling from the antenna to plasma will decrease plasma density and increase the electron temperature of the plasma. This fact may lead to an increase of plasma potential in the plasma and consequently an increase of ion energy of ions crossing the plasma sheath (the thin layer separating the plasma from the wall) and impinging on surfaces such as an RF window or other shield, resulting in unwanted sputtering of material from the chamber walls and the antenna in the case antenna is immersed in the plasma. In turn, the unwanted sputtering may degrade RF window lifetime and generate particles within the plasma source.

With respect to these and other considerations the present disclosure is provided.

### BRIEF SUMMARY

In one embodiment, an antenna assembly may include an antenna, a dielectric enclosure, surrounding the antenna, and a Faraday shield, disposed around the antenna, and arranged between the antenna and the dielectric enclosure. The Faraday shield may include a non-uniform opacity structure, wherein an opacity of the Faraday shield changes between a first region of the antenna and a second region of the antenna.

In another embodiment, an ion source is provided. The ion source may include a plasma chamber, an extraction plate, disposed on a side of the source chamber, and an antenna assembly, disposed within the plasma chamber. The antenna assembly may include a linear antenna, having a grounded end, and a powered end, the linear antenna extending along an antenna axis. The antenna assembly may also include a dielectric enclosure, surrounding the linear antenna, the dielectric enclosure being elongated along the antenna axis. The antenna assembly may further include a Faraday shield, disposed around the linear antenna, and arranged between the linear antenna and the dielectric enclosure, wherein the Faraday shield comprises a non-uniform opacity structure, wherein an opacity of the Faraday shield changes along the antenna axis.

In an additional embodiment, a processing apparatus is provided. The processing apparatus may include a plasma chamber, an extraction plate, disposed on a side of the source chamber, and a processing chamber, having a substrate holder, disposed opposite the extraction plate, and an antenna assembly, disposed within the plasma chamber. The antenna assembly may include a linear antenna, having a grounded end, and a powered end, the linear antenna extending along an antenna axis. The antenna assembly may also include a dielectric enclosure, surrounding the linear antenna, where the dielectric enclosure is elongated along the antenna axis. The antenna assembly may further include a Faraday shield, disposed around the linear antenna, and arranged between the linear antenna and the dielectric enclosure, wherein the Faraday shield comprises a non-uniform opacity structure, wherein an opacity of the Faraday shield changes along the antenna axis.

### BRIEF DESCRIPTION OF THE DRAWINGS

FIG. 1A shows a perspective view of a linear antenna assembly, according to embodiments of the disclosure;

FIG. 1B shows an end cross-sectional view of the linear antenna assembly of FIG. 1A;

FIG. 1C shows a perspective view of an ion source, in partial cross-section, according to embodiments of the disclosure;

FIG. 2A shows a plan view of an embodiment of a Faraday shield;

FIG. 2B shows a plan view of a linear antenna arranged according to the present embodiments;

FIG. 3A and FIG. 3B illustrate two different degrees of opacity of a linear antenna assembly, according to embodiments of the disclosure;

FIG. 4A is an exemplary illustration of the voltage variation along a linear antenna according to some embodiments of the disclosure;

FIG. 4B is an exemplary illustration of the voltage variation along a linear antenna according to other embodiments of the disclosure;

FIG. 5A shows a graph depicting opacity as a function of position along the X-axis in one embodiment of a Faraday shield;

FIG. 5B shows a graph depicting transmission as a function of position along the X-axis in the embodiment of a Faraday shield of FIG. 5A;

FIG. 6A depicts a 2-D contour plots obtained by HFSS modelling of electric field magnitude in the space around a linear antenna for the case of no Faraday shield;

FIG. 6B depicts 2-D contour plots obtained by HFSS modelling of electric field magnitude in the space around a linear antenna for the case of a uniform opacity Faraday shield;

FIG. 6C depicts 2-D contour plots obtained by HFSS modelling of electric field magnitude in the space around a linear antenna for the case of a non-uniform opacity Faraday shield arranged according to the present embodiments;

FIG. 7A depicts contour plots of the magnetic field distribution in the space around a linear antenna, for the case of no Faraday shield;

FIG. 7B depicts contour plots of the magnetic field distribution in the space around a linear antenna, for the case of a uniform opacity Faraday shield;

FIG. 7C depicts contour plots of the magnetic field distribution in the space around a linear antenna, for the case of a non-uniform opacity Faraday shield arranged according to the present embodiments;

FIG. 8A presents a top plan view of an exemplary processing system according to another embodiment of the disclosure;

FIG. 8B presents an end cross-sectional view of the processing system of FIG. 8A;

FIG. 9A shows a perspective view of another antenna assembly, according to further embodiments of the disclosure;

FIG. 9B shows a perspective view of an additional antenna assembly, according to other embodiments of the disclosure;

FIG. 10A shows a top plan view of an exemplary processing system, according to another embodiment of the disclosure; and

FIG. 10B shows an end view of the system of FIG. 10A.

The drawings are not necessarily to scale. The drawings are merely representations, not intended to portray specific parameters of the disclosure. The drawings are intended to depict exemplary embodiments of the disclosure, and therefore are not be considered as limiting in scope. In the drawings, like numbering represents like elements.

### DETAILED DESCRIPTION

An apparatus, system and method in accordance with the present disclosure will now be described more fully hereinafter with reference to the accompanying drawings, where embodiments of the system and method are shown. The system and method may be embodied in many different forms and are not be construed as being limited to the embodiments set forth herein. Instead, these embodiments are provided so this disclosure will be thorough and complete, and will fully convey the scope of the system and method to those skilled in the art.

Terms such as “top,” “bottom,” “upper,” “lower,” “vertical,” “horizontal,” “lateral,” and “longitudinal” may be used herein to describe the relative placement and orientation of these components and their constituent parts, with respect to the geometry and orientation of a component of a semiconductor manufacturing device as appearing in the figures. The terminology may include the words specifically mentioned, derivatives thereof, and words of similar import.

As used herein, an element or operation recited in the singular and proceeded with the word “a” or “an” are understood as potentially including plural elements or operations as well. Furthermore, references to “one embodiment” of the present disclosure are not intended to be interpreted as precluding the existence of additional embodiments also incorporating the recited features.

Provided herein are apparatus for improved ICP plasma sources that are driven by an internal antenna. In particular, a Faraday shield configuration is disclosed that is applicable to a linear rf antenna. As detailed below, a novel Faraday shield design is provided that exhibits a non-uniform opacity along the antenna length of a linear antenna. While this disclosure will focus on embodiments of a linear antenna, the present embodiments will cover a non-uniform opacity Faraday shield as applied to other antenna geometries and configurations.

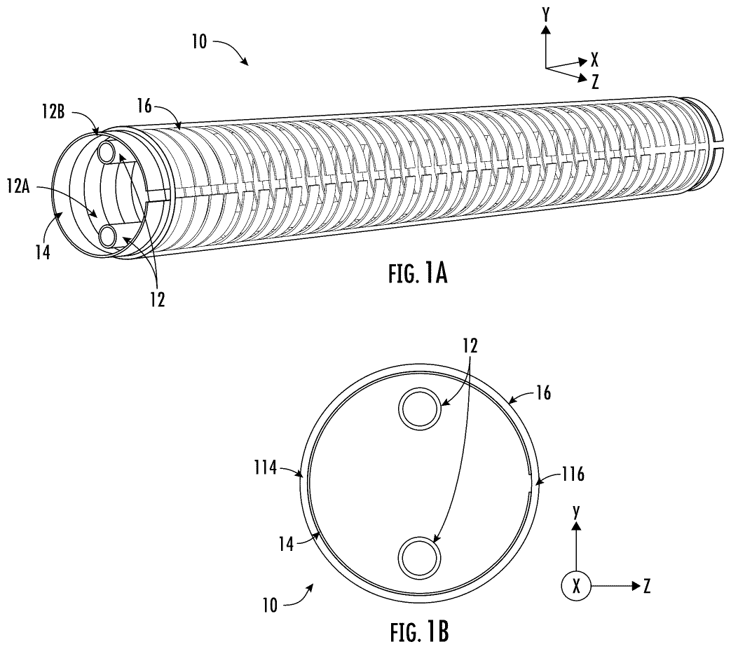

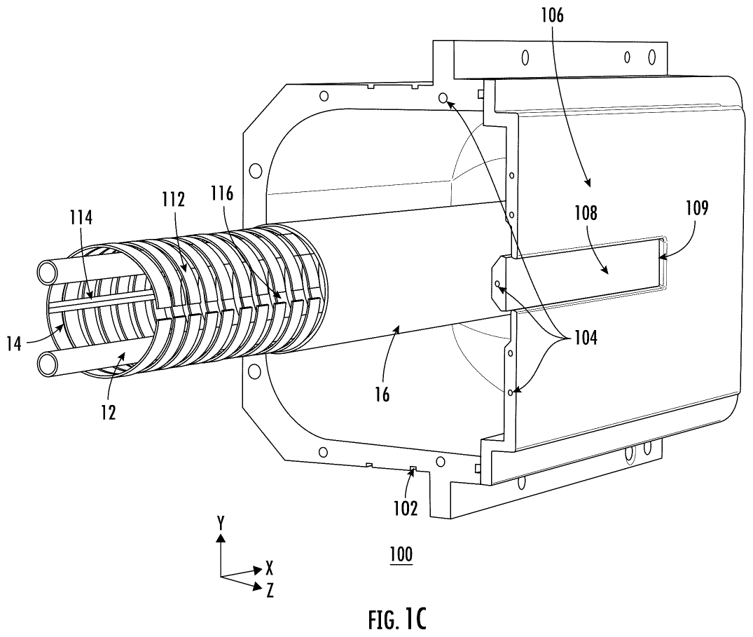

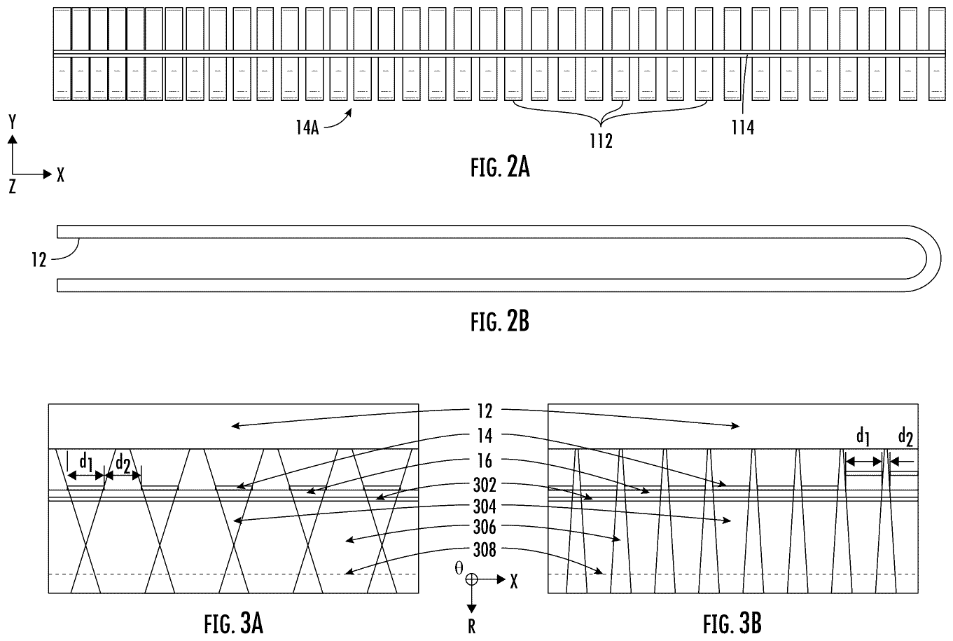

Turning to the figures, FIG. 1A shows a perspective view of a linear antenna assembly 10, according to embodiments of the disclosure. The linear antenna assembly 10 may include a linear antenna 12, having a grounded end, and a powered end. As shown, the linear antenna 12 extends along an antenna axis 12D (see FIG. 2B), meaning an axis parallel to the X-axis of the Cartesian coordinate system shown. The linear antenna 12 when coupled to receive an RF power signal, may act to generate a plasma by inductive coupling, discussed below. The linear antenna assembly 10 may further include a dielectric enclosure 16 that acts as an RF window, and surrounds the linear antenna 12, and is elongated along the antenna axis. The linear antenna assembly 10 may also include a Faraday shield 14, disposed around the linear antenna 12, and arranged between the linear antenna 12 and the dielectric enclosure 16, wherein the Faraday shield 14 forms a non-uniform opacity structure. As detailed below, the non-uniform opacity property means that an opacity of the Faraday shield 14 changes along the antenna axis (X-axis).

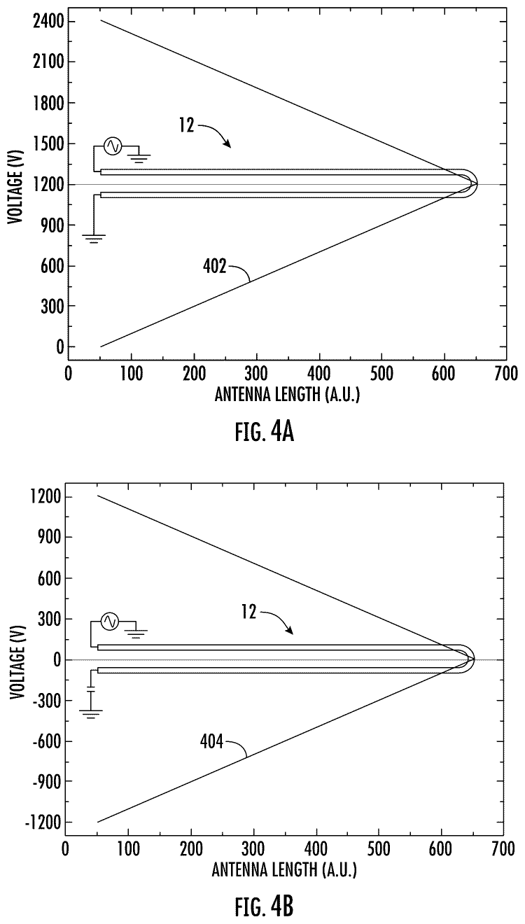

The linear antenna 12 may be a single conductive structure, such as a metallic structure that loops back upon itself as discussed below with respect to FIG. 4A, for example. In particular, the linear antenna 12 may have a U shape or hairpin structure, wherein a grounded end 12A and a powered end 12B of the linear antenna 12 are disposed next to one another. In particular embodiments, the linear antenna 12 may lie within the X-Y plane as shown in FIG. 1B.

In some embodiments, the linear antenna 12 may be a hollow tube that may be cooled by a cooling fluid provided within the hollow tube, such as a DI (de-ionized) water, ethylene glycol, silicone oil, nano-ester fluids etc. In addition, in some embodiments, a cooling gas may be provided in the enclosure formed by the dielectric enclosure 16, which cooling gas may surround the linear antenna and act as a coolant during operation.

In some embodiments, the Faraday shield 14 may be affixed to an inner wall of the dielectric enclosure 16, such as a patterned copper foil that is glued or cemented to the dielectric enclosure 16. In other embodiments, the Faraday shield 14 may be a separate conductive structure that is not adhered to the dielectric enclosure. The Faraday shield may be formed of a plurality of ribs, circumferentially surrounding the linear antenna.

Turning to FIG. 1C there is shown a perspective view of an ion source 100, in partial cross-section, including the linear antenna assembly 10. The ion source 100 may include a plasma chamber 102, which chamber may include passages 104. In various embodiments, the walls of plasma chamber 102 may be formed of conductive material. The ion source may include an extraction plate 106, disposed along a side of the plasma chamber 102, and may include a blocker 108 disposed adjacent to an extraction aperture 109 of the extraction plate 106, and acts to define ion beams that may be extracted from a plasma that is generated in the plasma chamber 102. The passages 104, in the extraction plate 106, blocker 108, and plasma chamber 102 may allow controllability of the temperature of plasma chamber walls. In other embodiments, a beam blocker may be omitted such that just an aperture or set of apertures is formed within the extraction plate 106. In other embodiments, two or more apertures and corresponding blockers may be present.

In some non-limiting embodiments, the plasma chamber 102 may be elongated along the X-axis, such that an extraction aperture 109 together with the linear antenna assembly 10 is also elongated along the X-axis. In particular embodiments, the linear antenna assembly 10 and extraction aperture 109 may be elongated to generate an elongated ‘ribbon’ ion beam when a plasma is formed in the plasma chamber 102, having a width up to 400 mm along the X-axis, with a height from several millimeters to several centimeters.

In operation, the role of the cylinder formed by the dielectric enclosure 16 is to allow transmission of the RF power from the linear antenna 12 to a rarefied gas that is provided inside the plasma chamber, but external to the dielectric enclosure 16. In particular, the dielectric enclosure 16 serves as a sealing wall to house the linear antenna 12 and define an internal chamber that separates and seals the internal chamber from the rest of the plasma chamber 102. In this manner, a separate ambient may be provided inside the cylindrical region defined be the dielectric enclosure 16, with respect to the ambient of the plasma chamber surrounding the dielectric enclosure 16.

As further depicted in FIG. 1C, the Faraday shield 14 may be formed of a plurality of ribs 112 that are arranged circumferentially around the linear antenna. The Faraday shield 14 may also have a spine 114 that extends parallel to the antenna axis and is arranged to connect the plurality of ribs 112 to one another. In some embodiments, the Faraday shield 14 may be formed from of a copper plate or foil, and may further include cuts 116 that are diametrically opposite to the spine 114. The function of the cuts 116 may be so that the ribs 112 do not form full rings to prevent closing paths for any induced eddy currents. As shown in FIG. 1B and FIG. 1C, the spine 114 and the cuts 116 may lie in the X-Z plane, so that the spine 114 is rotated 90 degrees within the Y-Z plane from the position of the linear antenna 12.

Turning now the FIG. 2A, there is shown a plan view of an embodiment of the Faraday shield 14, shown as Faraday shield 14A. For reference, a variant of the linear antenna 12 is shown separately in plan view in FIG. 2B. As illustrated, the hairpin structure of the linear antenna 12 is such that at a midway location 12C between the grounded end 12A and the powered end 12B, a curved portion, U-shaped portion, or similar shaped portion is present. As a result, the linear antenna 12 has two ‘legs’, shown as linear portion 12E and linear portion 12F. These two portions extend parallel to the antenna axis 12D and are connected to one another through the connecting portion at the midway location 12C, which connecting portion may be referred to herein as a U-shaped portion.

The Faraday shield 14A includes a plurality of ribs 112 that are arranged as a non-uniform opacity structure, wherein an opacity of the Faraday shield 14 changes along the antenna axis, meaning along the X-axis. A function of the non-uniform opacity of the Faraday shield 14A is to change capacitive coupling as a function of position along the X-axis between the linear antenna 12 and a plasma formed within the plasma chamber 102. By varying the capacitive coupling of linear antenna 12 and a plasma the resultant electron temperature and ion density may be varied along this direction.

To further explain this phenomenon, FIG. 3A and FIG. 3B illustrate two different degrees of opacity of a linear antenna assembly. In particular, these two figures provide cross sectional views of the linear antenna 12, a Faraday shield 14, and dielectric enclosure 16. The width or ribs 112 is illustrate by d₁ while the width of open regions between the ribs 112 is represented by d₂. The pitch between ribs 112 is therefore represented by d₁+d₂. Then the opacity (O) and transmission (T) are defined as

$$O = 1 - T = 1 - \frac{{d}_{2}}{{d}_{1} + {d}_{2}} \qquad ( 1 )$$

A bottom region of the figures illustrates a plasma region 304 that is separated from the dielectric enclosure 16 by a thin plasma sheath, shown as plasma sheath 302. In FIG. 3A and FIG. 3B are depicted radial slices (projections) 306 of the solid angles of electric field penetration into the plasma from open regions of the Faraday shield 14 where no metal or conductor is present. Also shown in these figures is the skin depth 308. Since the plasma is an electric conductor an rf field cannot penetrate into the plasma beyond the skin depth 308. In FIG. 3A, the radial slices 306 overlap within the skin depth 308, meaning a large number of electrons will interact with the electric field generated in the relatively larger transmissive (lower opacity) version of the Faraday shield 14 of FIG. 3A. In contrast, a small transmission (higher opacity) structure of the Faraday shield 14 of FIG. 3B, the radial slices 306 do not intersect at the skin depth 308, and may just intersect well beyond the skin depth 308. As such, a relatively smaller fraction of electrons will feel electric field lines. As such, the structure of FIG. 3A provides relatively greater capacitive coupling to a plasma, and the structure of FIG. 3B provides a relatively lower capacitive coupling to the plasma.

In sum, the comparison of FIGS. 3A and 3B illustrates the effectiveness of a Faraday shield in cutting capacitive coupling is a function of both Faraday shield opacity and the pitch of Faraday shield open zones. Since a plasma is quasi-neutral in the bulk the ionic component of a plasma is coupled electrostatically with the electronic component such that bombardment of the open zones by energetic ions accelerated in the plasma sheath 302 will occur. To take advantage of this phenomenon, in accordance with the present embodiments, a Faraday shield may be provided with non-uniform opacity to take into account the properties and behavior of the linear antenna 12.

Returning to FIG. 2, in the example shown the opacity of the Faraday shield 14A decreases from left to right of the figure along the X-axis. Said differently, the transmission or transmissivity of the Faraday shield 14A increases from left to right, meaning the amount of open zones where capacitive coupling to a plasma takes place increases from left to right. This increased capacitive coupling may be especially suitable for a linear antenna that is designed as in FIG. 1A, where RF power may be supplied from the left.

To illustrate this point further, FIG. 4A is a composite illustration showing a view of the linear antenna 12 along the X-axis, superimposed on a graph that depicts the voltage along the linear antenna 12 as a function of position along the X-axis, where the position may be in arbitrary units. The maximum voltage amplitude on the antenna is a function of power. For exemplification purposes it may be assumed to be 2400 V in this example. In inductively coupled plasma (ICP) sources control of the voltage distribution along the antenna will drive the amount of electrostatic coupling. As illustrated in FIG. 4A, an RF antenna in an ICP source may have one leg connected to an RF power supply-matching network system and the other leg connected to the electrical ground. For a linear antenna 12 the voltage distribution along the antenna length varies linearly from the powered end to the ground end. Thus, as shown by the voltage curve 402, a maximum voltage is reached at the end of the powered leg (top leg in the figure), half the maximum voltage is present in the midway location 12C of the antenna (the furthest right position), and zero voltage at the end of the grounded leg to the left. Generally, for this hairpin structure, the midway location 12C of the linear antenna 12 will be disposed at a distal curved portion (U-shaped portion) of the linear antenna 12, away from the grounded end and the powered end.

If a capacitor is inserted in the grounded leg of linear antenna 12, and this terminal capacitor has such capacitance value

$$C = \frac{2}{{( 2 π f )}^{2} L} \qquad ( 2 )$$

which result comes from the condition that capacitive reactance is equal to half the inductive reactance of the linear antenna 12, then the situation as depicted in FIG. 4B will be obtained. In Eq. (2) above f is the rf frequency and L the inductance of the antenna. For this case, illustrated by curve 404, the maximum voltage will be half of that voltage of the example of FIG. 4A and will occur in antiphase at the end of the powered leg and the end of the grounded leg, both of them being on the left side of the antenna. Then the middle of the linear antenna (meaning the furthest right position, which position is in a middle region of the linear antenna, midway between the powered end and ground end) will always have zero voltage. Thus, in the embodiment of FIG. 4B, the side 410 of the linear antenna 12 where the end of grounded leg and end of powered leg are disposed is a higher voltage side or region of the linear antenna 12, while the side 412 where the middle region is located is a lower voltage region of the linear antenna 12. Because at this location the voltage on the antenna is zero but there is not a connection to the ground, this point is called virtual ground. Besides the redistribution of the voltage along the antenna length and resonant reduction of the capacitive coupling, the termination capacitor configuration leads to the increase in plasma density.

Thus, for example, in the embodiment of FIG. 4B, the voltage on the linear antenna 12 decreases from left to right along the X-axis, in this case in a linear fashion. Recall that the azimuthal component E_{θ} generates rotational motion of electrons around antenna. It follows then that the electrostatic coupling to the plasma giving rise to ion bombardment is proportional to magnitude of the resultant of the radial Eᵣ and axial E_{z} components of the electric field

E_{rz}=\sqrt{Eᵣ²+E_{z}²} (3)

which field is proportional to the voltage on the linear antenna 12. For this reason, providing a Faraday shield 14 around the linear antenna 12, where the Faraday shield 14 has uniform opacity or transmission along the X-axis, will not be appropriate because this configuration will give rise to zones of monotonically varying electrostatic coupling and consequently non-uniform plasma density along the linear antenna 12. Said differently, and referring again to FIG. 1A, the plasma density and ion energy impinging on dielectric enclosure 16 is expected to be higher at the left side as compared to the right side, in the case where Faraday shield 14 has a uniform opacity along the X-axis. Referring also to FIG. 1C, differing plasma densities will translate into a non-uniform extracted ribbon-ion beam from the ion source 100.

In contrast, the Faraday shield 14A of FIG. 2, having a non-uniform opacity along the X-axis (and therefore a non-uniform transmission) will compensate for the effect of non-uniform voltage along the linear antenna 12 in the X-axis direction. In particular, the Faraday shield 14A exhibits a higher opacity at the locations of highest voltage on the linear antenna 12 (opposing ends of the antenna legs to the left of the figure), and exhibits a relatively smaller opacity at the location of smallest voltage (middle of the linear antenna, furthest to the right in FIG. 2). Thus, at the highest voltage position H along the antenna axis 12D (to the left in FIG. 2), the opacity of Faraday shield 14A is greatest, so as to compensate for the relatively greater capacitive coupling generated by the relatively higher voltage. Likewise, at the lowest voltage position L along the antenna axis (to the right in FIG. 2), the opacity of Faraday shield 14A is smallest, so as to compensate for the relatively lower capacitive coupling generated by the relatively lower voltage.

In one embodiment, providing a Faraday shield with a non-uniform opacity, such as a linearly decreasing opacity from the left side (where opposing ends of linear antenna 12 are located) to the right side (U-shaped portion of linear antenna, furthest right) will generally compensate for the deceased voltage along the linear antenna from left to right. However, the present inventors have discovered that a Faraday shield having a non-linear variation in opacity as a function of position along the X-axis may provide a more uniform electrostatic coupling along the X-axis. In particular, using high frequency simulation software (HFSS) modelling that a Faraday shield having a transmission obeying a Hill function along the linear antenna length will generate uniform electrostatic coupling and consequently uniform plasma density along the linear antenna.

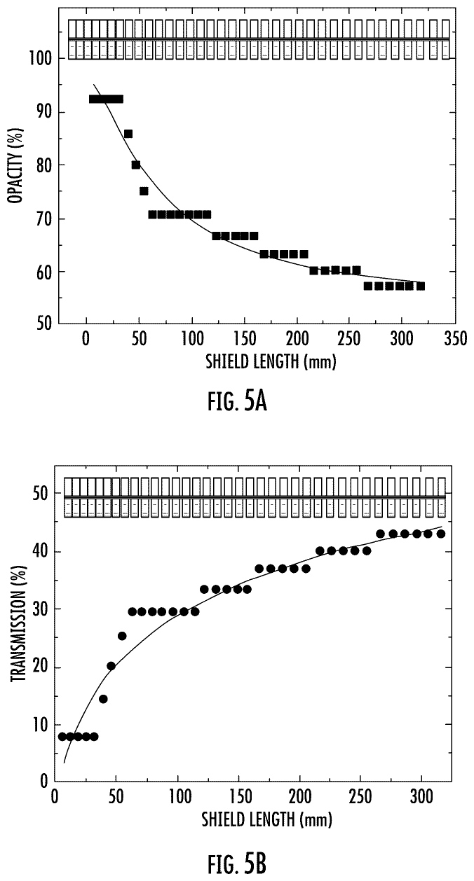

FIG. 5A and FIG. 5B are alternative composite representations showing the Faraday shield 14A superimposed on a graph depicting opacity (FIG. 5A) or transmission (FIG. 5B) as a function of position along the X-axis in one embodiment where the width of the Faraday shield 14A is 350 mm. The solid curve represents a Hill function, while the dots represent the opacity or transmission of the Faraday shield 14A at different points along the X-axis for an embodiment designed to emulate the Hill function. The Faraday shield 14A in this example has a transmission of 8% at the location of the antenna legs (where the rf voltage is highest) and then increases according to a Hill function up to 42% at the location of the virtual ground (furthest to the right).

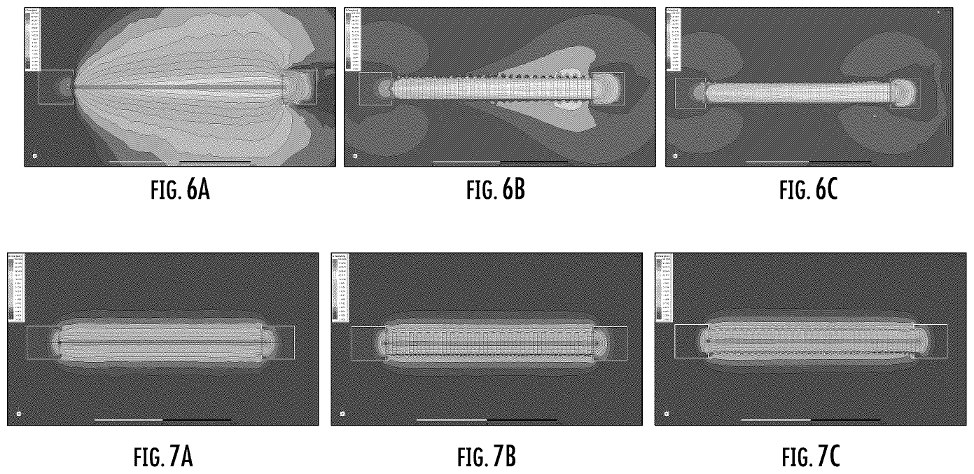

To illustrate the advantage of a non-uniform opacity Faraday shield, FIG. 6A, FIG. 6B, and FIG. 6C depict 2-D contour plots obtained by HFSS modelling of electric field magnitude in the space around a linear antenna for the case of no Faraday shield, uniform opacity Faraday shield, and non-uniform opacity Faraday shield, respectively. There are 16 contour lines logarithmically distributed in the range 0.1 V/m to 1200 V/m. In the absence of the Faraday shield the electric field protrudes deep into the plasma and has a truncated cone shaped distribution, lower field at the virtual ground and higher field at the antenna legs (FIG. 6a). For a Faraday shield with uniform transmission the electric field penetration into the plasma is considerably reduced but there is also present a truncated cone shaped distribution around the antenna legs. For a Faraday shield having a transmission obeying a Hill function, electric field penetration is drastically limited, exhibiting just a few bumps in the vicinity of the antenna.

FIG. 7A, FIG. 7B, and FIG. 7C depict contour plots of the magnetic field distribution in the space around a linear antenna, for the cases of no Faraday shield, uniform opacity Faraday shield, and non-uniform opacity Faraday shield, respectively. Maintaining a uniform distribution of the magnitude of the magnetic field may be equally important as maintaining a uniform distribution of the magnitude of the electric field because inductive power coupling scales with the magnitude of the temporal variation of the magnetic field. There are 16 contour lines logarithmically distributed in the range 0.1 V/m to 160 A/m. As can be seen in these figures, the magnetic field magnitude is uniform for all three cases, which result indicates an equal inductive coupling will occur at any location in the plasma along the antenna length.

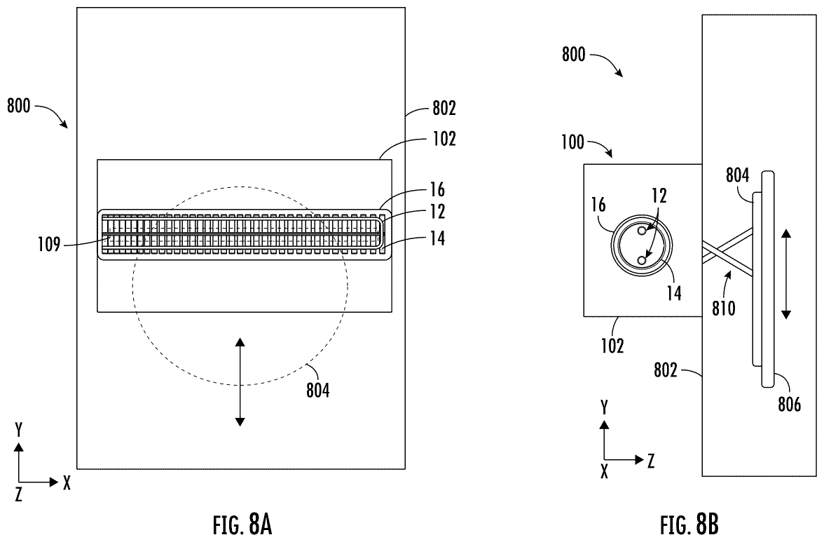

FIG. 8A presents a top plan view of an exemplary processing system, shown as system 800 according to another embodiment of the disclosure. The system 800 includes the aforementioned components of the ion source of FIG. 1C, where like components are labeled the same. For example, in the plasma chamber 102, the grounded end 12A and powered end 12B of linear antenna 12 are disposed on a first side 102A of the plasma chamber 102, next to one another, while the midway location 12C is disposed next to a second side 102B of the plasma chamber 102. In this view, a processing chamber 802 is disposed to house a substrate 804 that may be scanned along the Y-axis with respect to extraction aperture 109. As illustrated in the end cross-sectional view of FIG. 8B, an ion beam 810 may be extracted from the ion source 100. The ion beam 810 may be formed by two ion beamlets which beamlets impinge upon the substrate 804 at a symmetrically non-zero angles with respect to a perpendicular (meaning the Z-axis) to a main plane of the substrate 804 (meaning the X-Y plane in this example). As such, with the aid of scanning a substrate holder 806 along the Y-direction, an entirety of the substrate 804 may be exposed to an angled ribbon ion beam that is elongated to cover the substrate along the x-axis (see FIG. 8A). Moreover, with the aid of a non-uniform opacity Faraday shield, meaning the Faraday shield 14, the plasma density along the X-axis may be uniform, leading to a uniform ion beam current along the X-axis when the ion beam 810 is extracted from the ion source 100. In the view of FIG. 8B it may be assumed that a blocker 108 is present, leading to the extraction of two-symmetrically angled beamlets that form the total beam of ion beam 810, as in known extraction assemblies. However, in some embodiments, just a single ion beamlet may be extracted from an extraction aperture. In either case, the current may be substantially uniform due to the Faraday shield 14, which shield will generate uniform electric and magnetic fields, as shown in FIGS. 6C and 7C, respectively.

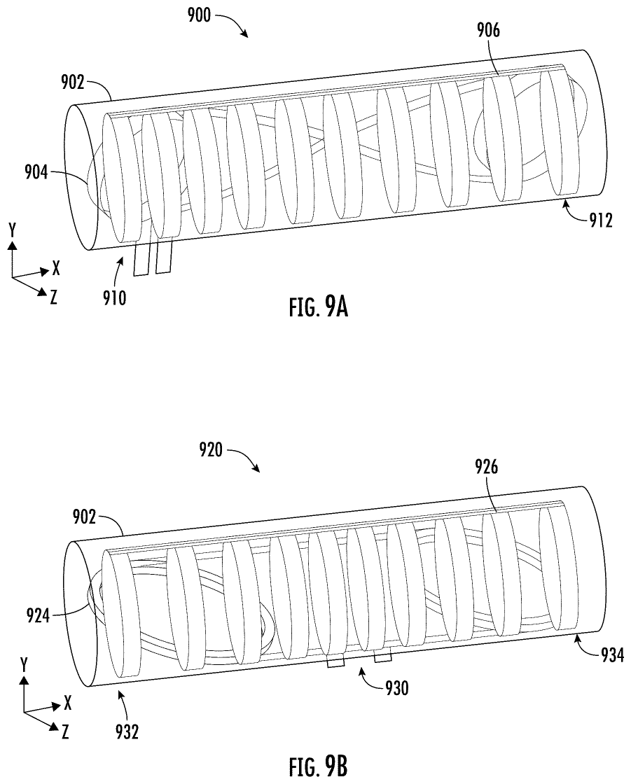

In additional embodiments, a non-uniform opacity Faraday shield where opacity varies along an antenna axis may be used in conjunction with other antenna designs, different than a linear antenna. FIG. 9A shows a perspective view of an antenna assembly 900, according to further embodiments of the disclosure. In this example, a helicon antenna 904 is enclosed by a dielectric shield 902. A non-uniform opacity Faraday shield 906 is provided between the helicon antenna 904 and the dielectric shield 902, and may function similarly to the embodiments detailed above with respect to a linear antenna configuration. An assumption may be that the voltage varies along the helicon antenna 904, such as from left to right in the figure (in particular, along the X-axis), such that the non-uniform opacity Faraday shield is arranged to change the opacity along the antenna axis 914, parallel to the X-direction, such as from a first position 910 along the antenna axis 914, toward the left, and a second position 912 along the antenna axis 914, to the right. In this manner, the non-uniform opacity may compensate for changes in voltage from the first position 910 to the second position 912.

FIG. 9B shows a perspective view of an antenna assembly 920, according to other embodiments of the disclosure. In this example, a Nagoya type-III antenna 924 is enclosed by a dielectric shield 902. A non-uniform opacity Faraday shield 926 is provided between the Nagoya type-III antenna 924 and the dielectric shield 902, and may function similarly to the embodiments detailed above with respect to a linear antenna configuration. A difference in this antenna assembly is that the Nagoya type-III antenna 924 has the powered leg and ground leg located in a middle region, which region is designated as middle position 930, of the antenna with respect to the left end 932 and the right end 934. In this case, therefore, a highest voltage of the Nagoya type-III antenna is present in the middle position 930, with voltage decreasing along the antenna axis 940 (parallel to the X-axis) toward the left end 932 and the right end 934. Accordingly, the non-uniform opacity Faraday shield 926 is arranged with a greater opacity in the middle position 930, and a lesser opacity toward an outer region at the left end 932 and toward another outer region at the right end 934, as illustrated in FIG. 9B.

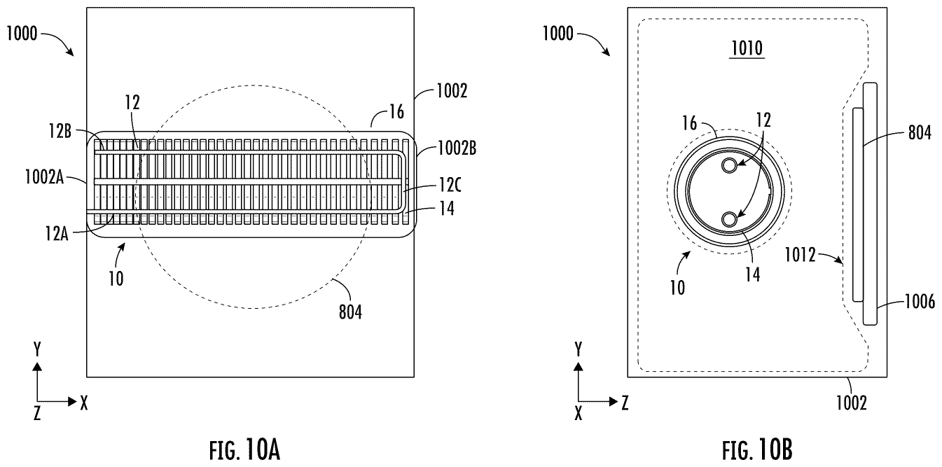

FIG. 10A presents a top plan view of an exemplary processing system, shown as system 800 according to another embodiment of the disclosure. The system 1000 includes the aforementioned components of the linear antenna assembly 10, where like components are labeled the same. In this embodiment, the linear antenna assembly 10 is disposed is a process chamber 1002, where the process chamber 1002 may double as a plasma chamber. As illustrated further in FIG. 10B, a substrate holder 1006, to support the substrate 804, is disposed in the same chamber, the process chamber 1002, as is the linear antenna assembly 10. Thus, when the linear antenna assembly 10 generates a plasma 1010, at least a front side of the substrate 804 may be immersed in the plasma 1010. In this embodiment, in the process chamber 1002, the grounded end 12A and powered end 12B of linear antenna 12 are disposed on a first side 1002A of the process chamber 1002, next to one another, while the midway location 12C is disposed next to a second side 1002B of the process chamber 1002. With the aid of a non-uniform-opacity Faraday shield, meaning the Faraday shield 14, the plasma density along the X-axis may be uniform, leading to a uniform ion current along the X-axis when a bias is applied to the substrate 804, and ions are extracted from the plasma 1010 across a plasma sheath 1012.

In view of the above, the present disclosure provides at least the following advantages. As a first advantage, the erosion of an rf window used with an ICP antenna may be reduced using the new non-uniform opacity Faraday shield configuration. In addition, a more uniform plasma density and consequently uniform extracted ribbon ion beam current density may be achieved in an ion source arranged according to the present embodiments.

While certain embodiments of the disclosure have been described herein, the disclosure is not limited thereto, as the disclosure is as broad in scope as the art will allow and the specification may be read likewise. Therefore, the above description are not to be construed as limiting. Thus, a non-uniform opacity Faraday shield of adequate shape and topology may be used in conjunction with solenoidal antenna, flat spiral antenna, helical antenna, or circular antenna to mitigate the detrimental effect of non-uniform voltage distribution along their length. Those skilled in the art will envision such modifications within the scope and spirit of the claims appended hereto.

1. An antenna assembly, comprising:
an antenna;
a dielectric enclosure, surrounding the antenna; and
a Faraday shield, disposed around the antenna, and arranged between the antenna and the dielectric enclosure, wherein the Faraday shield comprises a non-uniform opacity along an antenna axis of the antenna, wherein a first opacity of the Faraday shield at a first position along the antenna axis is greater than a second opacity of the Faraday shield at a second position along the antenna axis of the antenna.

2. The antenna assembly of claim 1, the Faraday shield being affixed to an inner wall of the dielectric enclosure.

3. The antenna assembly of claim 1, wherein the Faraday shield comprises a plurality of ribs, circumferentially surrounding the antenna.

4. The antenna assembly of claim 1,
wherein the antenna comprises a linear antenna, having a grounded end, and a powered end, the linear antenna extending along the antenna axis;
wherein the dielectric enclosure is elongated along the antenna axis.

5. The antenna assembly of claim 4, wherein the Faraday shield further comprises a plurality of ribs and a spine, the spine extending parallel to the antenna axis and arranged to connect the plurality of ribs to one another.

6. The antenna assembly of claim 4, wherein the linear antenna comprises a hairpin structure, the hairpin structure comprising a first linear portion that extends from the powered end, a second linear portion that extends from the grounded end, and a connecting portion, connecting the first linear portion to the second linear portion,
wherein the grounded end is disposed next to the powered end, wherein a side of the linear antenna where the grounded end and powered end are disposed comprises a higher voltage side of the linear antenna, and wherein a side of the linear antenna where the connecting portion is located comprises a lower voltage region of the linear antenna.

7. The antenna assembly of claim 6, wherein Faraday shield exhibits the first opacity at a first end of the Faraday shield, surrounding the powered end of the linear antenna, and exhibits the second opacity at a second end of the Faraday shield, surrounding the connecting portion of the linear antenna.

8. The antenna assembly of claim 7, wherein the non-uniform opacity varies along the antenna axis according to a Hill function.

9. A processing system, comprising:
a plasma chamber; and
an antenna assembly, disposed within the plasma chamber, the antenna assembly comprising:
a linear antenna, having a grounded end, and a powered end, the linear antenna extending along an antenna axis;
a dielectric enclosure, surrounding the linear antenna, the dielectric enclosure being elongated along the antenna axis; and
a Faraday shield, disposed around the linear antenna, and arranged between the linear antenna and the dielectric enclosure, wherein the Faraday shield comprises a non-uniform opacity along the antenna axis of the antenna, wherein a first opacity of the Faraday shield at a first location along the antenna axis is greater than a second opacity of the Faraday shield at a second location along the antenna axis.

10. The processing system of claim 9, the Faraday shield being affixed to an inner wall of the dielectric enclosure.

11. The processing system of claim 9, wherein the Faraday shield comprises a plurality of ribs, circumferentially surrounding the linear antenna.

12. The processing system of claim 11, wherein the Faraday shield further comprises a spine, the spine extending parallel to the antenna axis and arranged to connect the plurality of ribs to one another.

13. The processing system of claim 9, wherein the linear antenna comprises a hairpin structure, the hairpin structure comprising a first linear portion that extends from the powered end, a second linear portion that extends from the grounded end, and a connecting portion, connecting the first linear portion to the second linear portion,
wherein the grounded end is disposed next to the powered end, wherein a side of the linear antenna where the grounded end and powered end are disposed comprises a higher voltage side of the linear antenna, and wherein a side of the linear antenna where the connecting portion is located comprises a lower voltage region of the linear antenna.

14. The processing system of claim 13, wherein Faraday shield exhibits the first opacity at a first end of the Faraday shield, surrounding the powered end of the linear antenna, and exhibits the second opacity at a second end of the Faraday shield, surrounding the connecting portion of the linear antenna.

15. The processing system of claim 14, wherein the non-uniform opacity varies along the antenna axis according to a Hill function.

16. A processing system, comprising:
a plasma chamber;
an extraction plate, disposed on a side of the plasma chamber;
a processing chamber, having a substrate holder, disposed opposite the extraction plate; and
an antenna assembly, disposed within the plasma chamber, the antenna assembly, comprising:
a linear antenna, having a grounded end, and a powered end, the linear antenna extending along an antenna axis;
a dielectric enclosure, surrounding the linear antenna, the dielectric enclosure being elongated along the antenna axis; and
a Faraday shield, disposed around the linear antenna, and arranged between the linear antenna and the dielectric enclosure, wherein the Faraday shield comprises a non-uniform opacity structure, wherein an opacity of the Faraday shield changes along the antenna axis.

17. The processing system of claim 16, wherein the Faraday shield comprises a plurality of ribs, circumferentially surrounding the linear antenna; and
a spine, the spine extending parallel to the antenna axis and arranged to connect the plurality of ribs to one another.

18. The processing system of claim 16, wherein the linear antenna comprises a hairpin structure, the hairpin structure comprising a first linear portion that extends from the powered end, a second linear portion that extends from the grounded end, and a connecting portion, connecting the first linear portion to the second linear portion,
wherein the grounded end is disposed next to the powered end,
wherein a side of the linear antenna where the grounded end and powered end are disposed comprises a higher voltage side of the linear antenna, and wherein a side of the linear antenna where the connecting portion is located comprises a lower voltage region of the linear antenna.

19. The processing system of claim 18, wherein the Faraday shield exhibits a first opacity at a first end of the Faraday shield, surrounding the powered end of the linear antenna, and exhibits a second opacity, less that the first opacity, at a second end of the Faraday shield, surrounding the connecting portion of the linear antenna.

20. The processing system of claim 19, wherein the opacity varies along the antenna axis according to a Hill function.
